(19) United States
(12) Patent Application Publication
(10) Pub. No.: US 2019/0185684 A1
(43) Pub. Date: Jun. 20, 2019

(54) ELECTRICALLY CONDUCTIVE PASTE AND WIRING BOARD USING THE SAME

(71) Applicant: Yazaki Corporation, Tokyo (JP)

(72) Inventors: Maki YAMADA, Shizuoka (JP); Rie Katsumata, Shizuoka (JP); Yukito Aoyama, Shizuoka (JP)

(73) Assignee: Yazaki Corporation, Tokyo (JP)

(21) Appl. No.: 16/284,659

(22) Filed: Feb. 25, 2019

Related U.S. Application Data
(63) Continuation of application No. PCT/JP2017/021608, filed on Jun. 12, 2017.

(30) Foreign Application Priority Data
Aug. 21, 2016 (JP) 2016-184242

(51) Int. Cl. C09D 5/24; H05K 1/09; H01B 1/22; H05K 3/12; C09D 7/40; C09D 7/62; C09D 7/20; C09D 101/02

(52) U.S. Cl. CPC C09D 5/24; H05K 1/095; H01B 1/22; H05K 3/1283; C09D 7/67; H05K 2201/0224; C09D 7/69; C09D 7/62; C09D 7/20; C09D 101/02; H05K 2201/0257; C09D 7/68

(57) ABSTRACT

An electrically conductive paste contains: metal nanoparticles which are protected by an organic compound containing an amino group and have an average particle diameter of 30 nm to 400 nm; metal particles which are protected by a higher fatty acid and have an average particle diameter of 1 μm to 5 μm; an organic solvent; and a resin component consisting of a cellulose derivative. A conductor obtained by firing the electrically conductive paste has a film thickness of 30 μm or more and a specific resistance of 5.0×10⁻⁶ Ω·cm or less. In this way, the electrically conductive paste can reduce the resistance of the obtained conductor and to increase the amount of current flowing. A wiring board includes a conductor obtained from the electrically conductive paste.

### CROSS REFERENCE TO RELATED APPLICATION

This application is a Continuation of PCT Application No. PCT/JP2017/021608, filed on Jun. 12, 2017, and claims the priority of Japanese Patent Application No. 2016-184242, filed on Sep. 21, 2016, the content of all of which is incorporated herein by reference.

### BACKGROUND

### 1. Technical Field

The present invention relates to an electrically conductive paste and a wiring board using the electrically conductive paste. In detail, the present invention relates to an electrically conductive paste capable of obtaining a conductor having a specific resistance equivalent to that of silver bulk and a wiring board using the electrically conductive paste.

### 2. Related Art

In recent years, there has been a demand for a flexible printed wiring board capable of achieving miniaturization, thinning, three-dimensionalization and the like of a wire harness and its peripheral parts due to a reduction in cable arrangement space of a car. Particularly, a map lamp provided in the vicinity of the rearview mirror and located at the front center of the passenger compartment is required to be thin. In other words, with the evolution of automatic brake vehicles and automatically driven vehicles, the functions of cameras and sensor modules are intensified, and it is required to install these components on the back of the map lamp, so it is essential to reduce the thickness of the map lamp. Therefore, in order to reduce the thickness of the map lamp, the need for the flexible printed wiring board as described above is increasing.

As a flexible printed wiring board that meets the requirements of miniaturization, thinning, three-dimensionalization, etc., there is known a flexible printed circuit (FPC) in which an electric circuit is formed on a base material obtained by bonding a thin soft base film having electrical insulation and an electrically conductive metal such as copper foil. The circuit of the FPC is usually manufactured by a method called subtractive method. For example, a circuit can be formed by bonding a metal foil such as copper foil to a polyimide film and etching the metal foil. Such a subtractive method requires complicated and extremely long processes such as photolithography, etching, and chemical vapor deposition, and involves a problem of very low throughput. Further, in processes such as photolithography and etching, issues related to the environment, such as waste liquid, are constantly regarded as problems.

In order to solve the above problems, an additive method of forming a conductor pattern on an insulating plate, contrary to the subtractive method, is being studied. This method includes a plurality of types of methods, mainly including plating, printing of an electrically conductive paste or the like, vapor deposition of a metal on a necessary part of a substrate, arrangement of polyimide-sheathed cables on a substrate by adhesion, adhesion of a previously formed pattern to a substrate, and the like.

Among these additive methods, the printing method is one of the highest throughput methods. In the printing method, an electric circuit is e tablished mainly by using a film as a base material, further using an electrically conductive ink or an electrically conductive paste as a wire material, and combining an insulating film, a resist and the like therewith. Such an electrically conductive ink or an electrically conductive paste is composed of a metal component, an organic solvent, a reducing agent, an adhesive, and the like, and a conductor is formed by firing after application, and enables conduction.

As the electrically conductive paste, there are those using metal nanoparticles having a particle diameter of less than 1 μm as a main component and those using metal microparticles having a particle diameter exceeding 1 μm as a main component. However, when metal nanoparticles are used as the main component, the thickness of the applied film of the electrically conductive paste cannot be maintained, and as a result, the conductor obtained after firing would become a thin film. In addition, when metal microparticles are used as the main component, it is difficult to form a dense sintered body even if the electrically conductive paste is fired, so that the specific resistance of the obtained conductor would be increased. Therefore, conventional electrically conductive pastes cannot increase the amount of current flowing through conductors and it is difficult to apply them to wiring boards for automobiles. Therefore, an electrically conductive paste using metal nanoparticles having a particle diameter of less than 1 μm and metal microparticles having a particle diameter exceeding 1 μm has been developed.

As such an electrically conductive paste, Patent Document 1 discloses an electrically conductive paste containing: (A) a flake-shaped silver powder having an average particle diameter of 2 to 20 μm, a predetermined tap density and a content ratio of a carbon-containing compound of 0.5% by mass or less; (B) silver nanoparticles having an average particle diameter of 10 to 500 nm; and (C) a thermosetting resin. Further, Patent Document 2 discloses an electrically conductive metal paste using ultrafine metal particles having an average particle diameter of 100 nm or less, the surface of which is covered with a predetermined compound and a metal filler having an average particle diameter of 0.5 to 20 μm, and containing a resin component to be set by heating, an organic acid anhydride or an organic acid, and an organic solvent. Patent Document 3 discloses an electrically conductive ink containing fine metal particles (A) having an average particle diameter of 0.001 to 0.1 μm; a foil-like metal powder (B) having an average circle equivalent diameter of 1 to 20 μm and an average thickness of 0.01 to 0.5 μm; and a resin. Patent Document 4 discloses a low-temperature fired type silver paste containing, at least: metal nanoparticles covered with an organic protective colloid; a silver filler; and a dispersion medium, wherein the organic protective colloid and the dispersion medium have a decomposition temperature or boiling point of 70 to 250° C. Patent Document 5 discloses an electrically conductive paste for screen printing containing: metal nanoparticles protected by an organic compound containing a basic nitrogen atom and having an average particle diameter of 1 to 50 nm; metal particles having an average particle diameter exceeding 100 nm up to 5 μm; a deprotecting agent for the metal nanoparticles; and an organic solvent. Patent Document 6 discloses a silver particle coating composition containing: silver nanoparticles whose surface is covered with a protective agent containing an aliphatic hydrocarbon amine; a vinyl chloride-vinyl acetate copolymer resin; and a dispersion solvent.

Patent Document 1: Japanese Unexamined Patent Application Publication No. JP 2015-162392 A

Patent Document 2: International Publication No. WO 2002/035554

Patent Document 3: Japanese Unexamined Patent Application Publication No. JP 2005-248061 A

Patent Document 4: Japanese Unexamined Patent Application Publication No. JP 2008-9:1250 A

Patent Document 5: Japanese Patent Gazette No.JP 4835810 B2

Patent Document 6: international Publication No. WO 2016/052033

### SUMMARY

However, even if the electrically conductive pastes of Patent Documents 1 to 6 are used, the obtained conductors have a high specific resistance. Therefore, since the amount of current that can be passed through the conductors is small, it is difficult to use them for wiring boards for automobile applications.

The present invention has been made in view of such problems of the conventional techniques. An object of the present invention is to provide an electrically conductive paste capable of reducing the resistance of a conductor to be obtained and increasing the film thickness thereof and increasing the amount of current flowing through the conductor, and a wiring board using the electrically conductive paste.

An electrically conductive paste according to a first aspect of the present invention contains: metal nanoparticles which are protected by an organic compound containing an amino group and have an average particle diameter of 30 nm to 400 nm; metal particles which are protected by a higher fatty acid and have an average particle diameter of 1 μm to 5 μm; an organic solvent; and a resin component consisting of a cellulose derivative. A conductor obtained by firing the electrically conductive paste has a film thickness of 30 μm or more and a specific resistance of 5.0×10⁻⁶ Ω·cm or less.

An electrically conductive paste according to a second aspect of the present invention relates to the electrically conductive paste according to the first aspect, wherein the organic compound is an aliphatic hydrocarbon amine having: an aliphatic hydrocarbon group which is a linear or branched alkyl group having a total number of carbon atoms of 4 to 16; and one or two amino groups.

An electrically conductive paste according to third aspect of the present invention relates to the electrically conductive paste according to the first or second aspect, wherein the higher fatty acid is at least one of a saturated fatty acid and an unsaturated fatty acid each having a total number of carbon atoms of 12 to 24.

An electrically conductive paste according to a fourth aspect of the present invention relates to the electrically conductive paste according to any one of the first to third aspects, wherein the metal nanoparticles have an average particle diameter of 70 nm to 310 nm and the metal particles have an average particle diameter of 1 μm to 3 μm.

An electrically conductive paste according to a fifth aspect of the present invention relates to the electrically conductive paste according to any one of the first to fourth aspects, wherein the organic solvent has a total number of carbon atoms of 8 to 16, has a hydroxyl group, and further has a boiling point of 280° C. or lower.

An electrically conductive paste according to a sixth aspect of the present invention relates to the electrically conductive paste according to any one of the first to fifth aspects, wherein the resin component is made of a thermoplastic resin.

A wiring board according to a seventh aspect of the present invention includes a conductor obtained from the electrically conductive paste according to any one of the first to sixth aspects.

### DETAILED DESCRIPTION

### [Electrically Conductive Paste]

An electrically conductive paste according to the present embodiment contains metal nanoparticles which are protected by an organic compound containing an amino group and have an average particle diameter of 30 nm to 400 nm and metal particles which are protected by a higher fatty acid and have an average particle diameter of 1 μm to 5 μm.

The metal nanoparticles in the present embodiment have an average particle diameter of 30 nm to 400 nm. Usually, as the diameter of the metal particles decreases, the number of metal atoms present on the particle surface increases, so the melting point of the metal decreases. Therefore, such metal nanoparticles are used in the electrically conductive paste, thereby making it possible to form a conductor at a relatively low temperature. Further, since the average particle diameter of the metal nanoparticles is 30 nm to 400 nm, the gaps between the respective metal particles can be filled with the metal nanoparticles. Therefore, by firing the electrically conductive paste, the metal nanoparticles and the metal particles are sintered to form a dense sintered body, so that the conductivity of the obtained conductor can be increased. Incidentally, from the viewpoint of forming a denser sintered body and enhancing conductivity, the average particle diameter of the metal nanoparticles is more preferably 70 nm to 310 nm. As used herein, the average particle diameter of the metal nanoparticles means the median diameter (50% diameter, D50) measured by the dynamic light scattering method.

The metal constituting the metal nanoparticles preferably contains at least one element selected from the group consisting of gold, silver, copper, and platinum, and more preferably is composed at least one element selected from the group consisting of gold, silver, copper, and platinum. By using metal nanoparticles composed of these metals, a fine wire can be formed. Furthermore, the resistance value of the conductor after firing can be reduced, and the surface smoothness of the conductor can also be enhanced. Among these metals, it is preferable to use silver from the viewpoint that it is easily reduced, by firing of the electrically conductive paste, to form a dense sintered body, so that the specific resistance of the obtained conductor can be reduced.

Since the metal nanoparticles are increased in surface energy as a result of refinement, aggregation and precipitation of the metal nanoparticles are likely to occur. Therefore, in order to suppress the aggregation and precipitation of the metal nanoparticles, the surface of the metal nanoparticles is protected by an organic compound containing an amino group (—NH₂). As such an organic compound, it is more preferable to use an aliphatic hydrocarbon amine having: an aliphatic hydrocarbon group which is a linear or branched alkyl group having a total number of carbon atoms of 4 to 16; and one or two amino groups. These amine compounds can be easily removed by a firing process while maintaining a highly dispersed state of the metal nanoparticles, and thus can promote low-temperature sintering of the metal nanoparticles. As such an organic compound, at least one selected from the group consisting of n-butylamine, n-hexylamine, and n-octylamine can be used. From the viewpoint of suppressing aggregation of the metal nanoparticles, the amount of the organic compound to be added is preferably 1 to 3 mol per mol of the metal nanoparticles.

In addition to the metal nanoparticles described above, the electrically conductive paste according to the present embodiment further contains metal particles that are protected by a higher fatty acid and have an average particle diameter of 1 μm to 5 μm. By using such metal particles, it is possible to densify the conductor after firing and to reduce the specific resistance. Further, by using the metal nanoparticles and the metal particles in combination, it is possible to increase the thickness of the obtained conductor.

The average particle diameter of the metal particles is preferably 1 μm to 5 μm. When the average particle diameter of the metal particles falls within this range, it becomes possible to thicken the obtained conductor to increase the conductivity of the conductor. Even when the electrically conductive paste is applied to the insulating substrate by a screen printing method as will be described later, there is little possibility of clogging the metal particles in the screen printing mesh, so that it is possible to efficiently form a fine circuit. In addition, from the viewpoint of forming a denser sintered body together with the metal nanoparticles and increasing the conductivity, the metal particles more preferably have an average particle diameter of 1 μm to 3 μm. As used herein, the average particle diameter of the metal particles means the median diameter (50% diameter, D50) measured by the dynamic light scattering method.

As with the metal nanoparticles, the metal constituting the metal particles preferably contains at least one element selected from the group consisting of gold, silver, copper, and platinum, and more preferably is composed at least one element selected from the group consisting of gold, silver, copper, and platinum. By using the metal particles composed of these metals, the resistance value of the conductor after firing can be reduced, and the surface smoothness of the conductor can also be enhanced. Among these metals, it is preferable to use silver from the viewpoint that it is easily reduced, by firing of the electrically conductive paste, to form a dense sintered body, so that the specific resistance of the obtained conductor can be reduced.

The metal particles have lower surface energy than the metal nanoparticles, and aggregation and precipitation of the metal particles are less likely to occur. However, from the viewpoint of suppressing aggregation and precipitation of the metal particles, the surface of the metal particles protected by a higher fatty acid. The higher fatty acid is preferably at least one of a saturated fatty acid and an unsaturated fatty acid each having a total number of carbon atoms of 12 to 24. Specifically, as the higher fatty acid, at least one selected from the group consisting of myristic acid, palmitic acid, stearic acid, oleic acid, and linoleic acid, and derivatives thereof can be used. From the viewpoint of suppressing aggregation of the metal particles, the amount of the higher fatty acid to be added is preferably 1 to 3 mol per mol of the metal particles.

In the electrically conductive paste of the present embodiment, the ratio between the metal nanoparticles and the metal particles is not particularly limited, but is preferably, for example, 3:7 to 7:3 by mass ratio. When the ratio between the metal nanoparticles and the metal particles falls within this range, a conductor composed of a dense sintered body and improved in conductivity can be obtained. If the proportion of the metal nanoparticles is lower than this range, it may be difficult to satisfy the specific resistance of the obtained conductor. Conversely, when the proportion of the metal nanoparticles is higher than this range, there is a possibility that the viscosity of the electrically conductive paste may lower, thereby causing difficulty in satisfying the processability.

The electrically conductive paste of the present embodiment contains an organic solvent in order to highly disperse the metal nanoparticles which are protected by an organic compound containing an amino group and the metal particles which are protected by a higher fatty acid. The organic solvent is not particularly limited as long as it is capable of highly dispersing the metal nanoparticles and the metal particles and further capable of dissolving a resin component which will be described later. As the organic solvent, it is preferable to use one having a total number of carbon atoms of 8 to 16, having a hydroxyl group, and further having a boiling point of 280° C. or lower. Specifically, as the organic solvent, at least one selected from the group consisting of terpineol (C10, boiling point: 219° C.) dihydroterpineol (C10, boiling point: 220° C.), texanol (C12, boiling point: 260° C.), 2,4-dimethyl-1,5-pentadiol (C9, boiling point: 150° C.), and butyl carbitol (C8, boiling point: 230° C.) can be used. Also, as the organic solvent, at least one selected from the group consisting of isophorone (boiling point: 215° C.), ethylene, glycol (boiling point: 197° C.), butyl carbitol acetate (boiling point: 247° C.), 2,2,4-trimethyl-pentanediol diisobutyrate (C16, boiling point: 280° C.) can also be used.

The amount of the organic solvent to be added, in the electrically conductive paste, is not particularly limited, but is preferably adjusted so that the electrically conductive paste attains a viscosity which allows it to be applied by a screen printing method or the like. Specifically, the amount of the organic solvent to be added is preferably 2 to 10 parts by mass, more preferably 3 to 8 parts by mass, based on 100 parts by mass of the total of the metal nanoparticles protected by an organic compound containing an amino group and the metal particles protected by a higher fatty acid.

The electrically conductive paste of the present embodiment contains a resin component in order to increase the film thickness of the obtained conductor to lower the specific resistance. By adding the resin component, it becomes possible to thicken the applied film of the electrically conductive paste and to increase the film thickness of the conductor obtained after firing to 30 μm or more.

The resin component is preferably a thermoplastic resin. Examples of the thermoplastic resin include polyolefin resins, polyamide resins, elastomer (styrene, olefin, polyvinyl chloride (PVC), ester, and amide) resins, acrylic resins, and polyester resins. Specific examples of the thermoplastic resin include engineering plastics, polyethylene, polypropylene, nylon resins, acrylonitrile-butadiene-tyrene (ABS) resins, acrylic resins, ethylene acrylate resins, ethylene vinyl acetate resins, and polystyrene resins. Further, polyphenylene sulfide resins, polycarbonate resins, polyester elastomer resins, polyamide elastomer resins, liquid crystal polymers, polybutylene terephthalate resins, and the like can be indicated. One of these thermoplastic resins may be used alone, or two or more thereof may be used in combination.

As the resin component, it is preferable to use a chain polymer material (fiber type, resin) which forms fibers, for example, a cellulose derivative. Examples of the cellulose derivative include cellulose ethers, cellulose esters, and cellulose ether esters, but it is preferable to use cellulose ethers. The cellulose ethers include cellulose monoethers in which one kind of ether group is bonded to cellulose and cellulose mixed ethers in which two or more kinds of ether groups are bonded to cellulose. Specific examples of cellulose monoethers include methyl cellulose, ethyl cellulose, propyl cellulose, hydroxymethyl cellulose, hydroxyethyl cellulose, hydroxypropyl cellulose, and carboxymethyl cellulose. Specific examples of cellulose mixed ethers include methylethylcellulose, methylpropylcellulose, ethylpropylcellulose, hydroxymethylethylcellulose, hydroxypropylmethylcellulose, hydroxyethylmethylcellulose, and hydroxypropylmethylcellulose. One of these cellulose ethers may be used alone, or two or more thereof may be used in combination.

The amount of the resin component to be added, in the electrically conductive paste, is not particularly limited, but is preferably adjusted so that the thickness of the applied film of the electrically conductive paste can be increased. Specifically, it is preferable that the amount of the resin component be 0.1 to 5 parts by mass based on 100 parts by mass of the total of the metal nanoparticles protected by an organic compound containing an amino group and the metal particles protected by a higher fatty acid.

The electrically conductive paste of the present embodiment can contain an additive which improves the printing characteristics and conductor characteristics, such as an antifoaming agent, a surfactant, or a rheology control agent, within the range that does not adversely affect the dispersion stability of the paste and the performance of the conductor after firing.

Next, a method for preparing the electrically conductive paste of the present embodiment will be described. First, metal nanoparticles which are protected by an organic compound containing an amino group are prepared. The method for preparing the metal nanoparticles protected by the covering agent is not particularly limited, and the metal nanoparticles can be obtained by, for example, directly mixing powdered metal nanoparticles and the organic compound. Alternatively, the metal nanoparticles can be obtained by mixing powdered metal nanoparticles and the organic compound using an organic solvent and then drying the mixture. The drying method is also not particularly limited, and the organic solvent can be removed by vacuum drying or freeze drying.

Likewise, metal particles which are protected by a higher fatty acid are prepared. The method for preparing the metal particles protected by the covering agent is also not particularly limited, and the metal particles can be obtained, for example, by directly mixing powdered metal particles and a higher fatty acid. The metal particles can also be obtained by mixing powdered metal particles and a higher fatty acid using an organic solvent and then drying the mixture.

Then, the metal nanoparticles protected by an organic compound containing an amino group, the metal particles protected by a higher fatty acid, the organic solvent, the resin component, and, if necessary, an additive are mixed. The mixing method is not particularly limited, and it is preferable to mix the components by using, for example, a rotation/revolution centrifuge. In addition, defoaming treatment of the obtained mixture is carried out, as necessary. Through such a process, the electrically conductive paste of the present embodiment can be obtained.

As described above, the electrically conductive paste of the present embodiment contains metal nanoparticles which are protected by an organic compound containing an amino group and have an average particle diameter of 30 nm to 400 nm, metal particles which are protected by a higher fatty acid and have an average particle diameter of 1 μm to 5 μm, an organic solvent, and a resin component. Since the conductor obtained by firing the electrically conductive paste becomes a dense sintered body having an increased film thickness, the amount of current flowing can be increased. In other words, the conductor obtained has a film thickness of 30 μm or more and a specific resistance of 5.0×10⁻⁶ Ω·cm or less, and thus has the same specific resistance as that of silver bulk and can be applied to a wiring board for automobiles.

### [Wiring Board]

The wiring board according to the present embodiment includes a conductor obtained from the above-described electrically conductive paste. As described above, the conductor obtained from the electrically conductive paste of the present embodiment has a film thickness of 30 μm or more and a specific resistance of 5.0×10⁻⁶ Ω·cm or less. Therefore, the amount of current flowing can be increased, and the resulting wiring board can be suitably used for automobiles.

The wiring board of the present embodiment can be obtained by applying the electrically conductive paste onto a base material in a desired shape and then firing it. The base material that can be used for the wiring board is not particularly limited, and an electrically insulating film or plate material can be used. Such a base material has flexibility, and can be folded according to the use place. The material of the base material is not particularly limited and may be at least one selected from the group consisting of polyethylene terephthalate (PET), polyethylene naphthalate (PEN), polycarbonate (PC), polypropylene (PP), and polybutylene terephthalate (PBT).

The method for applying the electrically conductive paste onto the base material is not particularly limited, and the electrically conductive paste can be applied to the base material by a conventionally known method such as flexographic printing, gravure printing, gravure offset printing, offset printing, screen printing, or rotary screen printing.

The firing method after application of the electrically conductive paste onto the base material is also not particularly limited. For example, it is preferable to expose the base material having the electrically conductive paste applied thereto to hot air at 150° C. or higher. As a result, the organic compound, the higher fatty acid, the organic solvent, and the resin component in the electrically conductive paste are removed, and the metal nanoparticles and the metal particles are sintered, whereby a highly electrically conductive conductor can be obtained. It is more preferable that the base material having the electrically conductive paste applied thereto be exposed to hot air at 250° C. or higher. By raising the firing temperature, the obtained sintered body becomes denser, and thus it is possible to further reduce the resistance. Incidentally, the firing method is not limited to the hot air firing described above, and for example, plasma firing, light firing, or pulse wave firing can also be applied.

The wiring board provided with the conductor obtained from the electrically conductive paste may be provided with an insulating cover material for covering and protecting the surface of the conductor. As the insulating cover material, an insulating film or a resist can be used. The insulating cover material is preferably made of polyethylene terephthalate (PET), polyethylene naphthalate (PEN), polycarbonate (PC), polypropylene (PP), polybutylene terephthalate (PET), polyurethane (PU), or the like having an adhesive on one side. The resist to be used is preferably a thermosetting resist or a UV curable resist, and particularly preferably an epoxy resist or a urethane resist.

### EXAMPLES

Hereinafter, the present invention will be described in more detail with reference to examples, but is not limited to these examples.

### [Preparation of Sample]

First, as indicated in Tables 1 to 3, silver nanoparticles having a median diameter of 30 nm, 70 nm, 150 nm, 240 nm, 310 nm, or 600 nm were mixed with n-hexylamine or n-butylamine to thereby obtain silver nanoparticles protected by an alkylamine. The mass ratio between silver nanoparticles and n-hexylamine or n-butylamine was set to 1:1. Silver nanoparticles protected by an alkylamine were obtained by mixing silver nanoparticles having a median diameter of 310 nm with n-hexylamine and n-butylamine. The mass ratio among the silver nanoparticles, n-hexylamine, and n-butylamine was set to 1:0.5:0.5.

Furthermore, as indicated in Tables 1 to 3, silver particles having a median diameter of 0.8 μm, 1 μm, 2.3 μm, 2.9 μm, 5 μm, or 7 μm were mixed with stearic acid or oleic acid to thereby obtain silver particles protected by a higher fatty acid. The mass ratio between silver particles and stearic acid or oleic acid was set to 1:1. Also, silver particles having a median diameter of 1.8 μm and not treated with a higher fatty acid were prepared.

Then, the silver nanoparticles and silver particles obtained as described above and the organic solvent and resin component indicated in Tables 1 to 3 were agitated in a compounding ratio as indicated in each table by using a rotation/revolution centrifuge to thereby prepare an electrically conductive paste of each example. In addition, the following organic solvents and resin components were used.

### (Organic Solvent)

Texanol (2,2,4-trimethylpentane-1,3-diol monoisobutyrate) manufactured by Eastman Chemical Company
Terpineol (2-(4-methylcyclohex-3-enyl) propan-2-ol) manufactured by Yoneyama Yakuhin Kogyo Co., Ltd.
Cyclohexane manufactured by Idemitsu Kosan Co., Ltd.
Methyl ethyl ketone manufactured by Maruzen Petrochemical Co., Ltd.

### (Resin Component)

Ethylcellulose, ETHOCEL (registered trademark) STD 10, manufactured by The Dow Chemical Company
Epoxy resin, jER (registered trademark) main agent 828/curing agent ST11, manufactured by Mitsubishi Chemical Corporation
Urethane resin, UREARNO (registered trademark), manufactured by Arakawa Chemical Industries, Ltd.

TABLE 1

| | | | | Example 1 | Example 2 | Example 3 | Example 4 | Example 5 | Example 6 |
|---|---|---|---|---|---|---|---|---|---|
| Silver | Hexylamine | 70 | nm | — | — | — | 53.1 | — | — |
| Nanoparticles | | 240 | nm | — | 53.1 | — | — | — | — |
| (parts by mass) | | 310 | nm | — | | 53.1 | — | — | — |
| | Butylamine | 70 | nm | 53.1 | — | — | — | — | — |
| | | 150 | nm | — | — | — | — | 53.1 | — |
| | Hexylamlne + | 310 | nm | — | — | — | — | — | 53.1 |
| | Butylamine | | | | | | | | |
| Silver | Stearic Acid | 1 | μm | 40 | — | — | — | — | — |
| Particles | | 2.3 | μm | — | 40 | — | 40 | 40 | 40 |
| (parts by mass) | | 2.9 | μm | — | — | 40 | — | — | — |
| | Oleic Acid | 1 | μm | — | — | — | — | — | — |
| | | 2.3 | μm | — | — | — | — | — | — |
| | | 2.9 | μm | — | — | — | — | — | — |
| | Not Treated | 1.8 | μm | — | — | — | — | — | — |

| | | | | | | | |
|---|---|---|---|---|---|---|---|
| Organic | Texanol | 6.8 | 6.8 | 6.8 | — | — | 6.8 |
| Solvents | Terpineol | — | — | — | 6.8 | 6.8 | — |
| (parts by mass) | Cyclohexane | — | — | — | — | — | — |
| | Methyl Ethyl Ketone | — | — | — | — | — | — |
| Resin | Ethylcellulose | 0.1 | 0.1 | 0.1 | 0.1 | 0.1 | 0.1 |
| Components | Epoxy Resin | — | — | — | — | — | — |
| (parts by mass) | Urethane Resin | — | — | — | — | — | — |
| Characteristics | Film Thickness (μm) | 37 | 33 | 32 | 30 | 30 | 36 |
| | Specific Resistance (Ω · cm) | 4.4 × 10⁻⁶ | 3.0 × 10⁻⁶ | 2.3 × 10⁻⁶ | 4.3 × 10⁻⁶ | 3.6 × 10⁻⁶ | 3.8 × 10⁻⁶ |
| | Viscosity (Pa · s) | 250 | 15 | 30 | 13 | 15 | 80 |
| | Appearance When Applied | ◯ (good) | ◯ (good) | ◯ (good) | ◯ (good) | ◯ (good) | ◯ (good) |

TABLE 2

| | | | | Example 7 | Example 8 | Example 9 | Example 10 | Example 11 | Example 12 |
|---|---|---|---|---|---|---|---|---|---|
| Silver | Hexylamine | 70 | nm | — | — | — | — | — | — |
| Nanoparticles | | 240 | nm | — | 53.1 | — | 53.1 | — | — |
| (parts by mass) | | 310 | nm | 53.1 | — | 53.1 | — | 53.1 | 53.1 |
| | Butylamine | 70 | nm | — | — | — | — | — | — |
| | | 150 | nm | — | — | — | — | — | — |
| | Hexylamine + | 310 | nm | — | — | — | — | — | — |
| | Butylamine | | | | | | | | |
| Silver | Stearic Acid | 1 | μm | — | 40 | — | 40 | — | — |
| Particles | | 2.3 | μm | — | — | 40 | — | — | — |
| (parts by mass) | | 2.9 | μm | 40 | — | — | — | — | — |
| | Oleic Acid | 1 | μm | — | — | — | — | 40 | — |
| | | 2.3 | μm | — | — | — | — | — | — |
| | | 2.9 | μm | — | — | — | — | — | 40 |
| | Not Treated | 1.8 | μm | — | — | — | — | — | — |

| | | | | | | | |
|---|---|---|---|---|---|---|---|
| Organic | Texanol | 6.6 | 6.4 | 5.4 | — | 6.8 | 6.8 |
| Solvents | Terpineol | — | — | — | 2.9 | — | — |
| (parts by mass) | Cyclohexane | — | — | — | — | — | — |
| | Methyl Ethyl Ketone | — | — | — | — | — | — |
| Resin | Ethylcellulose | 0.3 | 0.5 | 1.5 | 4 | 0.1 | 0.1 |
| Components | Epoxy Resin | — | — | — | — | — | — |
| (parts by mass) | Urethane Resin | — | — | — | — | — | — |
| Characteristics | Film Thickness (μm) | 37 | 40 | 43 | 49 | 30 | 36 |
| | Specific Resistance (Ω · cm) | 3.1 × 10⁻⁶ | 3.9 × 10⁻⁶ | 4.0 × 10⁻⁶ | 4.9 × 10⁻⁶ | 3.3 × 10⁻⁶ | 3.8 × 10⁻⁶ |
| | Viscosity (Pa · s) | 60 | 80 | 150 | 200 | 23 | 33 |
| | Appearance When Applied | ◯ (good) | ◯ (good) | ◯ (good) | ◯ (good) | ◯ (good) | ◯ (good) |

TABLE 3

| | | | | Comparative | Comparative | Comparative | Comparative | Comparative |
|---|---|---|---|---|---|---|---|---|
| | | | | Example 1 | Example 2 | Example 3 | Example 4 | Example 5 |
| Silver | Hexylamine | 300 | nm | 93.1 | — | — | — | — |
| Nanoparticles | | 240 | nm | — | — | 53.1 | 53.1 | 53.1 |
| (parts by mass) | | 600 | nm | — | 53.1 | — | — | — |
| | Butylamine | 70 | nm | — | — | — | — | — |
| | | 150 | nm | — | — | — | — | — |
| | Hexylamine + | 310 | nm | — | — | — | — | — |
| | Butylamine | | | | | | | |
| Silver | Stearic Acid | 0.8 | μm | — | — | 40 | — | — |
| Particles | | 2.3 | μm | — | 40 | — | — | — |
| (parts by mass) | | 5 | μm | — | — | — | — | — |
| | Oleic Acid | 7 | μm | — | — | — | 40 | — |
| | | 1 | μm | — | — | — | — | — |
| | | 2.3 | μm | — | — | — | — | — |
| | Not Treated | 2.9 | μm | — | — | — | — | — |
| | Not Treated | 1.8 | μm | — | — | — | — | 40 |
| Organic | Texanol | | | 6.8 | 6.8 | 6.8 | 6.8 | 6.8 |
| Solvents | Terpineol | | | — | — | — | — | — |
| (parts by mass) | Cyclohexane | | | — | — | — | — | — |
| | Methyl Ethyl Ketone | | | — | — | — | — | — |
| Resin | Ethylcellulose | | | 0.1 | 0.1 | 0.1 | 0.1 | 0.1 |
| Components | Epoxy Resin | | | — | — | — | — | — |
| (parts by mass) | Urethane Resin | | | — | — | — | — | — |
| Characteristics | Film Thickness (μm) | | | Cannot be | 45 | 32 | 39 | 33 |
| | | | | Measured | | | | |
| | Specific Resistance (Ω · cm) | | | Cannot be | 5.3 × 10⁻⁶ | 8.0 × 10⁻⁶ | 7.6 × 10⁻⁶ | 8.1 × 10⁻⁶ |
| | | | | Measured | | | | |
| | Viscosity (Pa · s) | | | 16 | 45 | 18 | 35 | 10 |
| | Appearance When Applied | | | Cannot be | ◯ (good) | ◯ (good) | ◯ (good) | ◯ (good) |
| | | | | Printed | | | | |

### [Evaluation]

The film thickness and specific resistance of the respective conductors obtained by firing the electrically conductive pastes of Examples 1 to 12 and Comparative Examples 1 to 5 obtained as described above and the viscosity of the respective electrically conductive pastes and the appearance thereof when applied were evaluated as follows. The evaluation results are collectively indicated in Tables 1 to 3.

### (Film Thickness of Conductor)

The film thickness of the respective conductors was measured by stylus scanning method with reference to Japanese Industrial Standard JIS H8501 (methods of thickness test for metallic coatings). As a device, a contact film thickness measuring device (Alpha-Step D-500 manufactured by KLA Tencor Corporation) was used.

Specifically, first, a circuit of each of the electrically conductive pastes having a width of 1 mm and a length of 10 cm and a circuit of each of the electrically conductive pastes having a width of 5 mm and a length of 10 cm were printed on a polyimide substrate by using a screen printing machine. The substrate on which the electrically conductive pastes were printed was allowed to stand at room temperature for 30 minutes and then fired with hot air at 150° C. for 30 minutes to prepare a sample of each example.

Next, the film thickness of the Ag thin film on the obtained sample was measured at three points, i.e., at a portion of 1 cm from each end and a portion of 5 cm at the center. The speed of the needle at the time of measurement was 0.1 mm/s and the stylus pressure was 15 mg. The needle was moved in the direction perpendicular to the circuit for measurement. The average value of the film thicknesses at the three places was used as the evaluation result of each example.

### (Specific Resistance of Conductor)

The specific resistance of the respective conductors was measured with reference to JIS K 7194 (testing method for resistivity of electrically conductive plastics with a four-point probe array). As a device, a four-point probe resistivity measuring device (resistivity measuring device Sigma-5+manufactured by NPS Inc.) was used.

Specifically, first, a circuit of each of the electrically conductive pastes having a width of 2 mm and a length of 10 cm was printed on a polyimide substrate by using a screen printing machine. The substrate on which the electrically conductive pastes were printed was allowed to stand at room temperature for 30 minutes and then fired with hot air 150° C. for 30 minutes to prepare a sample of each example.

Next, for the Ag thin film on the obtained sample, the surface resistance was measured at three points, i.e., at a portion of 1 cm from each end and a portion of 5 cm at the center. The surface resistance was measured in a state where the needle was placed in parallel with the circuit.

### (Viscosity of Electrically Conductive Paste)

The viscosity of each of the electrically conductive pastes was measured with reference to JIS K5600-2-3 (Testing methods for paints—Part 2: Characteristics and stability of paints—Section 3: Viscosity (Cone and plate methods)). As a device, a rotary viscometer (Rheometer RS100-CS manufactured by HAKKE) was used.

Specifically, first, after preparation of the electrically conductive paste of each example, it was allowed to stand at room temperature (25° C.) to keep the temperature constant. The temperature controller was also used during viscosity measurement to control the temperature of the electrically conductive paste at 25° C. Then, an electrically conductive paste was filled between the cone and plate at the measuring part, rotation was performed so as to attain the specified shear rate, and the viscosity at that time was measured. At this time, the viscosity was measured while varying the shear rate from 0 S⁻¹ to 100 S⁻¹ over 5 minutes, and the value when the shear rate was 10 S⁻¹ was used as the viscosity of each example.

(Appearance of Electrically Conductive Paste when Applied)

When the film thickness of the above-described conductor was measured, it was visually confirmed whether or not the electrically conductive paste was uniformly applied without rubbing against the electrically conductive paste after the screen printing. Then, the case where there was no rubbing against the electrically conductive paste and uniform coating applied was evaluated as “o(good)”.

As indicated in Tables 1 and 2, in the electrically conductive pastes of Examples 1 to 12 according to the present embodiment, the film thickness of each of the conductors obtained is 30 μm or more and the specific resistance is 5.0×10⁻⁶ Ω·cm or less. Therefore, the conductors can be suitably used for a wiring board for automobiles.

In contrast, as indicated in Table 3, since the electrically conductive paste of Comparative Example 1 did not contain silver particles, it was difficult to increase the film thickness of the electrically conductive paste, and screen printing could not be performed. In addition, the electrically conductive paste of Comparative Example 2 resulted in deterioration of specific resistance because the average particle diameter of silver nanoparticles exceeded 400 nm. This is presumably because the silver nanoparticles were too large and could not be filled in the gaps between the silver particles so that a dense conductor could not be formed.

In the electrically conductive paste of Comparative Example 3, since the average particle diameter of silver particles was less than 1 μm, the specific resistance was deteriorated. This is presumably because, even if silver nanoparticles were used, the silver particles were too small and thus a dense conductor could not be formed. In the electrically conductive paste of Comparative Example 4, since the average particle diameter of the silver particles was more than 5 μm, the specific resistance was deteriorated. Therefore, it is understood that the average particle diameter of the metal particles is preferably 5 μm or less.

In the electrically conductive paste of Comparative Example 5, since the surface of silver particles was not protected by a higher fatty acid, the specific resistance was deteriorated. This is presumably because silver particles aggregated because no protective agent was present on the surface of the silver particles and dense conductors could not be formed even if silver nanoparticles were used.

Although the present invention has been described with reference to the embodiments and the comparative examples, the present invention is not limited thereto, and various modifications are possible within the scope of the gist of the present invention.

According to the electrically conductive paste of the present invention, the conductor obtained by firing it has a film thickness of 30 μm or more and a specific resistance of 5.0×10⁻⁶ Ω·cm or less. Therefore, it is possible to reduce the resistance of the obtained conductor and to increase the amount of current flowing.

What is claimed is:

1. An electrically conductive paste comprising:
metal nanoparticles which are protected by an organic compound containing an amino group and have an average particle diameter of 30 nm to 400 nm;
metal particles which are protected by a higher fatty acid and have an average particle diameter of 1 μm to 5 μm;
an organic solvent; and
a resin component consisting of a cellulose derivative,
wherein a conductor obtained by firing the electrically conductive paste has a film thickness of 30 μm or more and a specific resistance of 5.0×10⁻⁶ Ω·cm or less.

2. The electrically conductive paste according to claim 1, wherein the organic compound is an aliphatic hydrocarbon amine having: an aliphatic hydrocarbon group which is a linear or branched alkyl group having a total number of carbon atoms of 4 to 16; and one or two amino groups.

3. The electrically conductive paste according to claim 1, wherein the higher fatty acid is at least one of a saturated fatty acid and an unsaturated fatty acid each having a total number of carbon atoms of 12 to 24.

4. The electrically conductive paste according to claim 1, wherein the metal nanoparticles have an average particle diameter of 70 nm to 310 nm and the metal particles have an average article diameter of 1 μm to 3 μm.

5. The electrically conductive paste according to claim 1, wherein the organic solvent has a total number of carbon atoms of 8 to 16, has a hydroxyl group, and further has a boiling point of 280° C. or lower.

6. A wiring board comprising a conductor obtained from the electrically conductive paste according to claim 1.
